(19) United States
(12) Patent Application Publication
(10) Pub. No.: US 2021/0060705 A1
(43) Pub. Date: Mar. 4, 2021

(54) WORKPIECE CUTTING METHOD

(71) Applicant: HAMAMATSU PHOTONICS K.K., Hamamatsu-shi, Shizuoka (JP)

(72) Inventor: Takeshi SAKAMOTO, Hamamatsu-shi, Shizuoka (JP)

(73) Assignee: HAMAMATSU PHOTONICS K.K., Hamamatsu-shi, Shizuoka (JP)

(21) Appl. No.: 16/605,028

(22) PCT Filed: Apr. 12, 2018
(86) PCT No.: PCT/JP2018/015440

§ 371 Date: Oct. 14, 2019

(30) Foreign Application Priority Data
Apr. 17, 2017 (JP) 2017-081558

(51) Int. Cl. B23K 26/38; B23K 26/40

(52) U.S. Cl. CPC B23K 26/38; B23K 26/40

(57) ABSTRACT

An object cutting method includes: a first step of preparing an object; a second step of irradiating the object with a laser light to form at least one row of modified regions in a single crystal silicon substrate of the object along each of a plurality of lines to cut and to form a fracture so as to extend between the at least one row of modified regions and a second main surface of the object; and a third step of, after the second step, performing reactive ion etching on the object from the second main surface side to form a groove opening to the second main surface, along each of the plurality of lines to cut. In the third step, a black silicon layer is fowled on the second main surface of the object and an inner surface of the groove while the reactive ion etching is performed.

### TECHNICAL FIELD

An aspect of the present invention relates to an object cutting method.

### BACKGROUND ART

As the conventional technology related to the object cutting method, Patent Literature 1 discloses that a modified region is formed in an object to be processed along a line to cut by irradiating the object with a laser light and then etching is performed along the modified region by performing etching on the modified region.

### CITATION LIST

### Patent Literature

Patent Literature 1: Japanese Patent No. 5197586

### SUMMARY OF INVENTION

### Technical Problem

In recent years, in an object cutting method, it may be preferred to cut the object using reactive ion etching. In this case, for example, it is required to control a progress of reactive ion etching in order to manage a quality of a semiconductor chip obtained by cutting.

Therefore, an object of one aspect of the present invention is to provide an object cutting method capable of controlling a progress of reactive ion etching.

### Solution to Problem

An object cutting method according to an aspect of the present invention includes: a first step of preparing an object to be processed including a single crystal silicon substrate and a functional device layer provided on a first main surface side; a second step of, after the first step, irradiating the object with a laser light to form at least one row of modified regions in the single crystal silicon substrate along each of a plurality of lines to cut and to form a fracture in the object so as to extend between the at least one row of modified regions and a second main surface of the object along each of the plurality of lines to cut; a third step of, after the second step, performing reactive ion etching on the object from a second main surface side to form a groove opening to the second main surface, in the object along each of the plurality of lines to cut, in which in the third step, a black silicon layer is formed on the second main surface of the object and an inner surface of the groove while the reactive ion etching is performed.

In the object cutting method, the reactive ion etching is performed, from the second main surface side, on the object in which the fracture is formed to extend between the at least one row of modified regions and the second main surface of the object. In this way, the reactive ion etching is selectively progressed along the fracture from the second main surface side, so the groove having a narrow and deep opening is formed along each of the plurality of lines to cut. Here, it is possible to end the progress of the reactive ion etching using the black silicon layer by forming the black silicon layer 6 on the second main surface of the object and the inner surface of the groove while the reactive ion etching is performed. That is, it is possible to control the progress of the reactive ion etching.

In the object cutting method according to the aspect of the present invention, in the second step, the at least one row of modified regions may be formed along each of the plurality of lines to cut by forming the plurality of rows of modified regions arranged in a thickness direction of the object, and the fracture may be formed to extend between the modified regions adjacent to each other in the plurality of rows of modified regions. In this way, it is possible to progress the reactive ion etching deeper and selectively.

In the object cutting method according to the aspect of the present invention, in the second step, the at least one row of modified regions may be formed along each of the plurality of lines to cut by forming a plurality of modified spots arranged along each of the plurality of lines to cut, and the fracture may be formed to extend between the modified spots adjacent to each other among the plurality of modified spots. In this way, it is possible to selectively progress the reactive ion etching with higher efficiency.

In the object cutting method according to an aspect of the present invention, in the third step, the black silicon layer may be formed by mixing oxygen into an etching gas. According to this configuration, the formation of the black silicon layer can be specifically realized.

In the object cutting method according to an aspect of the present invention, in the third step, oxygen may be mixed into the etching gas when the groove has a predetermined depth. According to this configuration, the progress of the reactive ion etching can end by forming the black silicon layer so that the groove with a predetermined depth is formed.

The object cutting method according to the aspect of the present invention may further include: a fourth step of, after the third step, cutting the object into a plurality of semiconductor chips along each of the plurality of lines to cut by sticking an extension film to the second main surface side and extending the extension film. According to this configuration, the object can be reliably divided into the plurality of semiconductor chips.

### Advantageous Effects of Invention

According to an aspect of the present invention, it is possible to provide the object cutting method capable of controlling the progress of the reactive ion etching.

### BRIEF DESCRIPTION OF DRAWINGS

FIG. 1 is a schematic structural diagram of a laser processing apparatus used for forming a modified region.

FIG. 2 is a plan view of an object to be processed as a target for forming the modified region.

FIG. 3 is a sectional view of the object taken along the line III-III of FIG. 2.

FIG. 4 is a plan view of the object after laser processing.

FIG. 5 is a sectional view of the object taken along the line V-V of FIG. 4.

FIG. 6 is a sectional view of the object taken along the line VI-VI of FIG. 4.

FIG. 7 is a sectional view illustrating an experimental result on an object cutting method.

FIG. 8 is a sectional view illustrating an experimental result on the object cutting method.

FIG. 9 is a sectional view illustrating an experimental result on the object cutting method.

FIG. 10 is a sectional view illustrating an experimental result on the object cutting method.

FIG. 11 is a diagram illustrating an experimental result on the object cutting method.

FIG. 12 is a diagram illustrating an experimental result on the object cutting method.

FIG. 13 is a diagram illustrating an experimental result on the object cutting method.

FIG. 14 is a diagram illustrating an experimental result on the object cutting method.

FIG. 15 is a diagram illustrating an experimental result on the object cutting method.

FIG. 16 is a diagram illustrating an experimental result on the object cutting method.

FIG. 17 is a diagram illustrating an experimental result on the object cutting method.

FIG. 18 is a diagram illustrating an experimental result on the object cutting method.

FIG. 19 is a diagram illustrating an experimental result on the object cutting method.

FIG. 20 is a diagram illustrating an experimental result on the object cutting method.

FIG. 21 is a perspective view of the object illustrating an experimental result on the object cutting method.

FIG. 22 is a cross-sectional view for describing the object cutting method according to one embodiment.

FIG. 23 is a cross-sectional view for describing the object cutting method according to one embodiment.

FIG. 24 is a cross-sectional view for describing the object cutting method according to one embodiment.

FIG. 25 is a cross-sectional view for describing the object cutting method according to one embodiment.

FIG. 26 is a cross-sectional view for describing the object cutting method according to one embodiment.

FIG. 27 is a cross-sectional view for describing the object cutting method according to one embodiment.

### Description of Embodiments

Hereinafter, embodiments of the present disclosure will be explained in detail with reference to drawings. In the drawings, the same or equivalent parts will be denoted by the same reference signs, without redundant description.

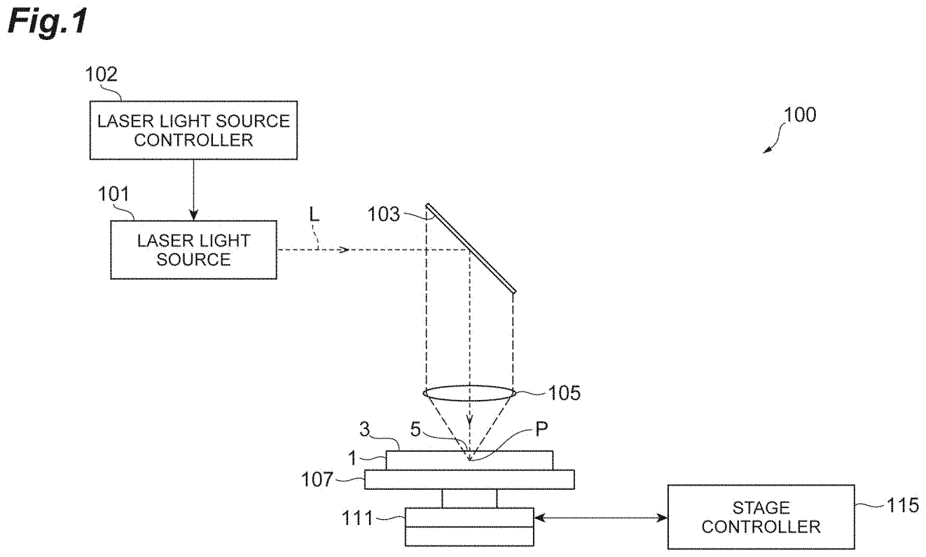

In an object cutting method according to an embodiment, laser light is converged at an object to be processed to form a modified region within the object along a line to cut. Therefore, forming of the modified region will be explained at first with reference to FIGS. 1 to 6.

As illustrated in FIG. 1, a laser processing apparatus 100 includes a laser light source 101 that causes laser light L to oscillate in a pulsating manner and is a laser light emission unit, a dichroic mirror 103 disposed to change a direction of the optical axis (optical path) of the laser light L by 90°, and a converging lens 105 configured to converge the laser light L. The laser processing apparatus 100 further includes a support table 107 for supporting an object to be processed 1 irradiated with the laser light L converged by the converging lens 105, a stage 111 for moving the support table 107, a laser light source controller 102 for controlling regulating the laser light source 101 in order to adjust the output (pulse energy, light intensity), the pulse width, the pulse waveform, and the like of the laser light L, and a stage controller 115 for regulating the movement of the stage 111.

In the laser processing apparatus 100, the laser light L emitted from the laser light source 101 changes the direction of its optical axis by 90° with the dichroic mirror 103 and then is converged by the converging lens 105 into the object 1 mounted on the support table 107.

At the same time, the stage 111 is shifted, so that the object 1 moves relative to the laser light L along a line 5 to cut. This forms a modified region in the object 1 along the line 5 to cut. While the stage 111 is shifted here for relatively moving the laser light L, the converging lens 105 may be shifted instead or together therewith.

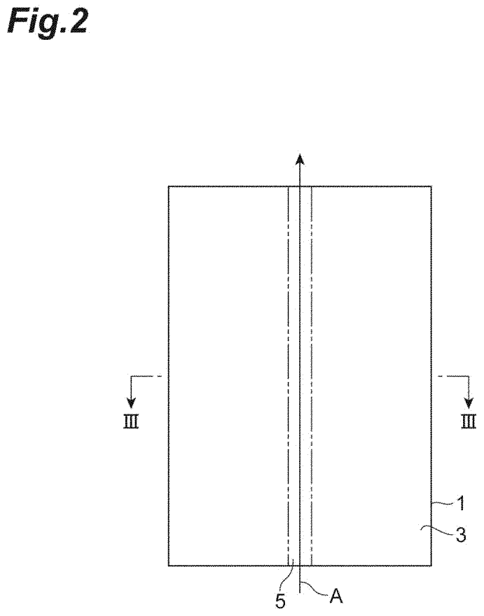

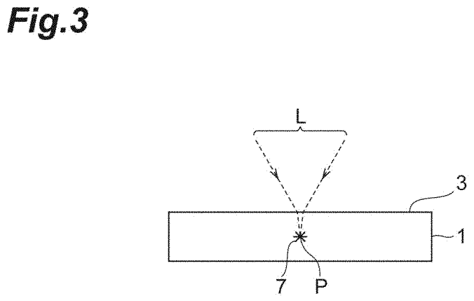

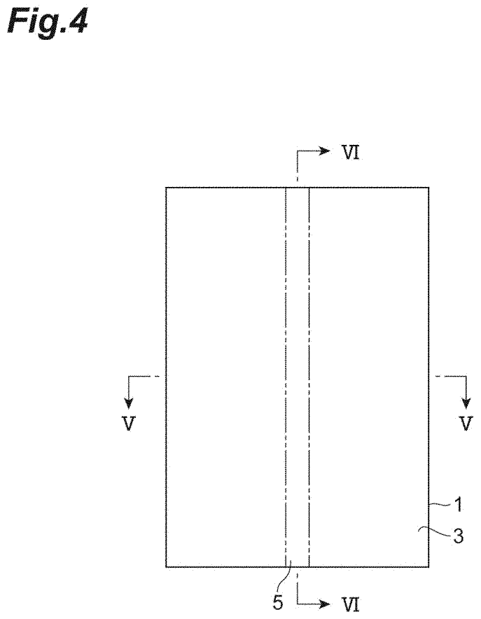

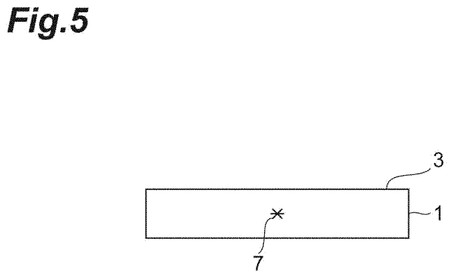

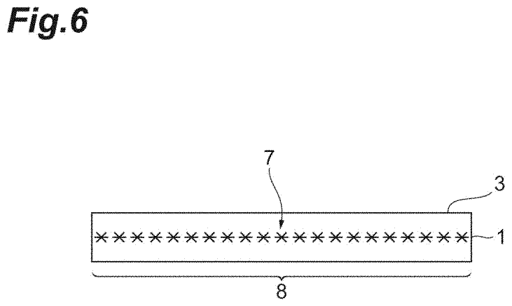

Employed as the object 1 is a planar member (for example, a substrate or a wafer), examples of which include semiconductor substrates formed of semiconductor materials and piezoelectric substrates formed of piezoelectric materials. As illustrated in FIG. 2, in the object 1, the line 5 to cut is set for cutting the object 1. The line 5 to cut is a virtual line extending straight. When forming a modified region within the object 1, the laser light L is relatively moved along the line 5 to cut (that is, in the direction of arrow A in FIG. 2) while locating a converging point (converging position) P within the object 1 as illustrated in FIG. 3. This forms a modified region 7 in the object 1 along the line 5 to cut as illustrated in FIG. 4, FIG. 5 and FIG. 6, and the modified region 7 formed along the line 5 to cut acts as a cutting start region 8.

The converging point P is a position at which the laser light L is converged. The line 5 to cut may be curved instead of being straight, a three-dimensional one combining them, or one specified by coordinates. The line 5 to cut may be one actually drawn on a front surface 3 of the object 1 without being restricted to the virtual line. The modified region 7 may be formed either continuously or intermittently. The modified region 7 may be formed either in rows or dots and may be formed at least in the object 1. There are cases where fractures are formed from the modified region 7 acting as a start point, and the fractures and modified region 7 may be exposed at outer surfaces (front surface 3, rear surface, and outer peripheral surface) of the object 1. The laser light entrance surface for forming the modified region 7 is not limited to the front surface 3 of the object 1 but may be the rear surface of the object 1.

In a case where the modified region 7 is formed in the object 1, the laser light L is transmitted through the object 1 and absorbed, in particular, in the vicinity of the converging point P in the object 1. Thus, the modified region 7 is formed in the object 1 (that is, internal absorption laser processing). In this case, the front surface 3 of the object 1 hardly absorbs the laser light L, and thus does not melt. In a case where the modified region 7 is formed on the front surface 3 or the rear surface of the object 1, the laser light L is absorbed, in particular, in the vicinity of the converging point P on the front surface 3 or the rear surface. Thus, the front surface 3 or the rear surface is melted and removed, and a removed portion such as a hole or a groove is formed (surface absorption laser processing).

The modified region 7 refers to a region having physical characteristics such as density, a refractive index, and mechanical strength, which have attained states different from those of their surroundings. Examples of the modified region 7 include molten processed regions (meaning at least one of regions resolidified after having been once molten, those in the molten state, and those in the process of resolidifying from the molten state), crack regions, dielectric breakdown regions, refractive index changed regions, and their mixed regions. Other examples of the modified region 7 include areas where the density of the modified region 7 has changed from that of an unmodified region and areas formed with a lattice defect in a material of the object 1. In a case where the material of the object 1 is single crystal silicon, the modified region 7 also refers to a high dislocation density region.

The molten processed regions, refractive index changed regions, areas where the modified region 7 has a density different from that of the unmodified region, and areas formed with a lattice defect may further incorporate a fracture (cut or microcrack) therein or at an interface between the modified region 7 and the unmodified region. The incorporated fracture may be formed over the whole surface of the modified region 7 or in only some or a plurality of parts thereof. The object 1 includes a substrate made of a crystal material having a crystal structure. For example, the object 1 includes a substrate made of at least any of gallium nitride (GaN), silicon (Si), silicon carbide (SiC), LiTaO₃, and sapphire (Al₂O₃). In other words, the object 1 includes a gallium nitride substrate, a silicon substrate, a SiC substrate, a LiTaO₃ substrate, or a sapphire substrate, for example. The crystal material may be either anisotropic crystal or isotropic crystal. The object 1 may include a substrate made of an amorphous material having an amorphous structure (non-crystalline structure) or may include, for example, a glass substrate.

In the embodiment, the modified region 7 can be formed by forming a plurality of modified spots (processing scars) along the line 5 to cut. In this case, the modified region 7 is formed by integrating the plurality of modified spots. The modified spot is a modified portion formed by a shot of one pulse of pulsed laser light (that is, one pulse of laser irradiation: laser shot). Examples of the modified spots include crack spots, molten processed spots, refractive index changed spots, and those in which at least one of them is mixed. As for the modified spots, their size and lengths of fractures occurring therefrom can be controlled as necessary in view of the required cutting accuracy, the demanded flatness of cut surfaces, the thickness, kind, and crystal orientation of the object 1, and the like. In the embodiment, the modified spots can be formed along the line 5 to cut, for the modified region 7.

[Experimental Result on Object Cutting Method]

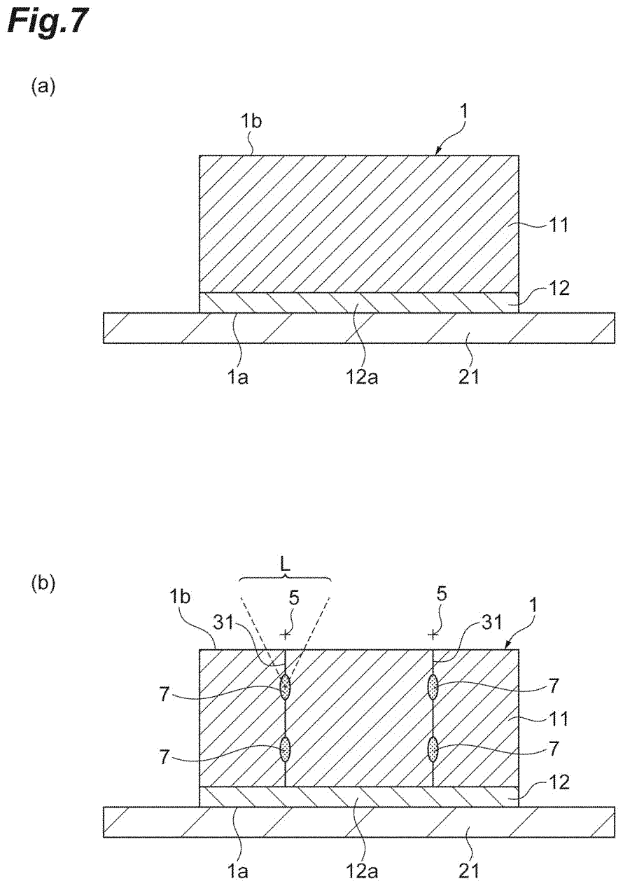

Firstly, an example of an object cutting method will be explained with reference to FIGS. 7 to 10. Constituents illustrated in FIGS. 7 to 10 are schematic, and an aspect ratio and the like of each constituent are different from those of the practical one. As illustrated in FIG. 7(a), an object to be processed 1 including a single crystal silicon substrate 11 and a functional device layer 12 provided on a first main surface 1a side is prepared, and a protective film 21 is stuck to the first main surface 1a of the object 1. The functional device layer 12 includes a plurality of functional devices 12a (light receiving device such as a photodiode, a light emitting device such as a laser diode, or a circuit device formed as a circuit, and the like) arranged along the first main surface 1a in a matrix, for example. A second main surface 1b of the object 1 (main surface on an opposite side of the first main surface 1a) is a surface of the single crystal silicon substrate 11 on an opposite side of the functional device layer 12.

As illustrated in FIG. 7(b), if the object 1 is irradiated with laser light L by using the second main surface 1b as a laser light entrance surface, a plurality of rows of modified regions 7 is formed in the single crystal silicon substrate 11 along each of a plurality of lines 5 to cut, and a fracture 31 is formed in the object 1 along each of the plurality of lines 5 to cut. The plurality of lines 5 to cut is set in, for example, a grid so as to pass between the functional device 12a adjacent to each other in a case of being viewed from a thickness direction of the object 1. A plurality of rows of modified regions 7 formed along each of the plurality of lines 5 to cut is arranged in the thickness direction of the object 1. The fracture 31 extends at least between one row of modified regions 7 on the second main surface 1b side and the second main surface 1b.

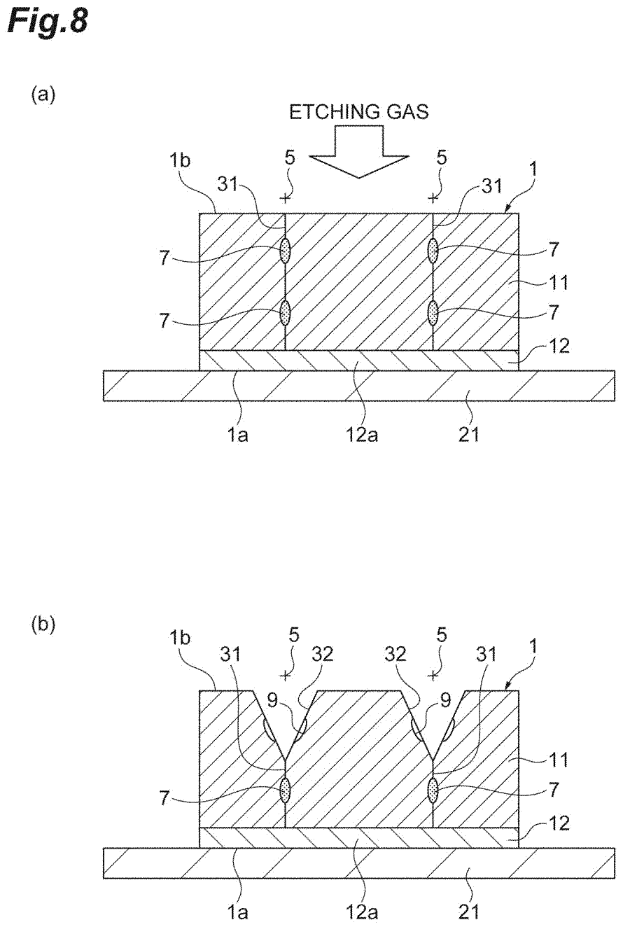

If, as illustrated in FIG. 8(a), dry etching is performed on the object 1 from the second main surface 1b side, a groove 32 is formed in the object 1 along each of the plurality of lines 5 to cut, as illustrated in FIG. 8(b). The groove 32 is, for example, a V groove (groove having a V-shaped section) opening to the second main surface 1b. Dry etching selectively progresses from the second main surface 1b side along the fracture 31 (that is, along each of the plurality of lines 5 to cut), and thereby the groove 32 is formed. Then, an uneven region 9 is formed on the inner surface of the groove 32 in a manner that one row of modified region 7 on the second main surface 1b side is removed by dry etching. The uneven region 9 has an uneven shape corresponding to the one row of modified regions 7 on the second main surface 1b side. Details thereof will be described later.

Performing dry etching on the object 1 from the second main surface 1b side has the meaning that dry etching is performed on the single crystal silicon substrate 11 in a state where the first main surface 1a is covered with the protective film and the like, and the second main surface 1b (or etching protection layer (described later) 23 in which a gas passage region is formed along each of the plurality of lines 5 to cut) is exposed to an etching gas. In particular, in a case of performing reactive ion etching (plasma etching), performing dry etching means irradiation of the second main surface 1b (or etching protection layer (described later) 23 in which a gas passage region is formed along each of the plurality of lines 5 to cut) with reactive species in plasma.

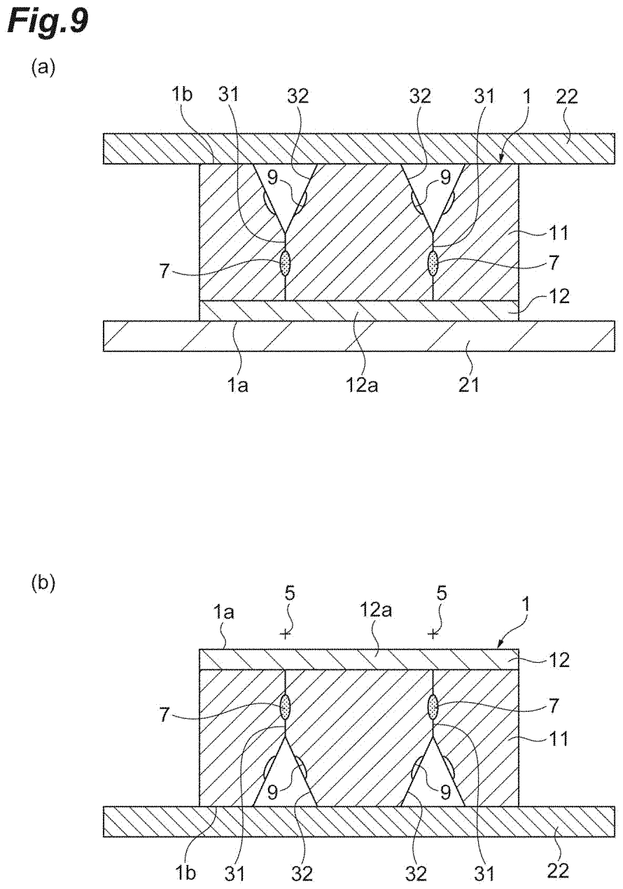

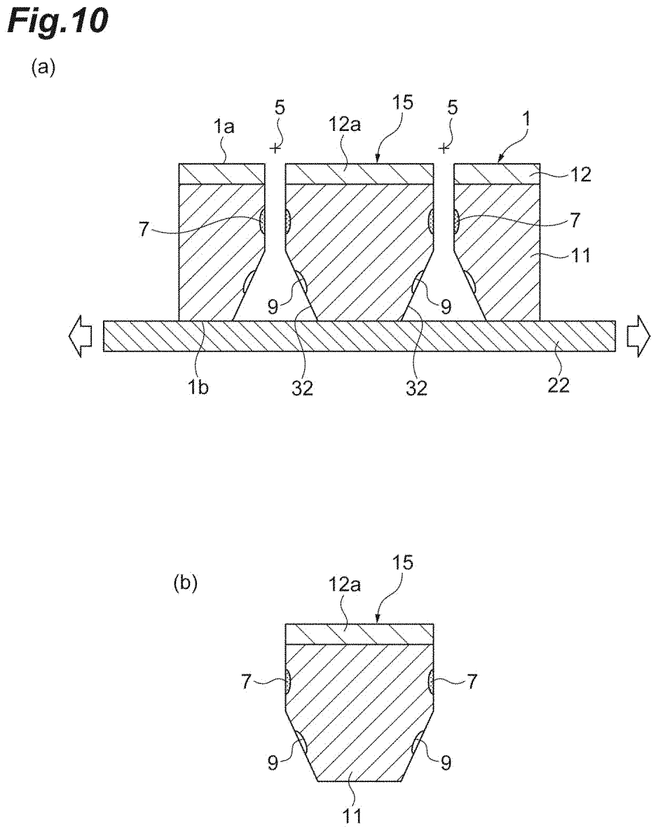

Then, as illustrated in FIG. 9(a), an extension film 22 is stuck to the second main surface 1b of the object 1. As illustrated in FIG. 9(b), the protective film 21 is removed from the first main surface 1a of the object 1. As illustrated in FIG. 10(a), if the extension film 22 is extended, the object 1 is cut into a plurality of semiconductor chips 15 along each of the plurality of lines 5 to cut. Then, as illustrated in FIG. 10(b), the semiconductor chips 15 are picked up.

Next, an experimental result in a case of performing dry etching after the modified region is formed as in the above-described example of the object cutting method will be explained.

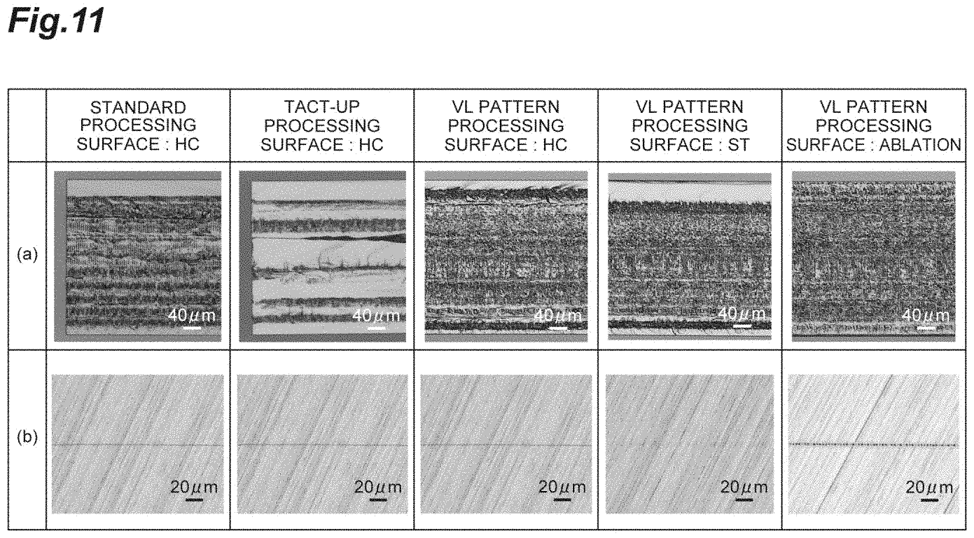

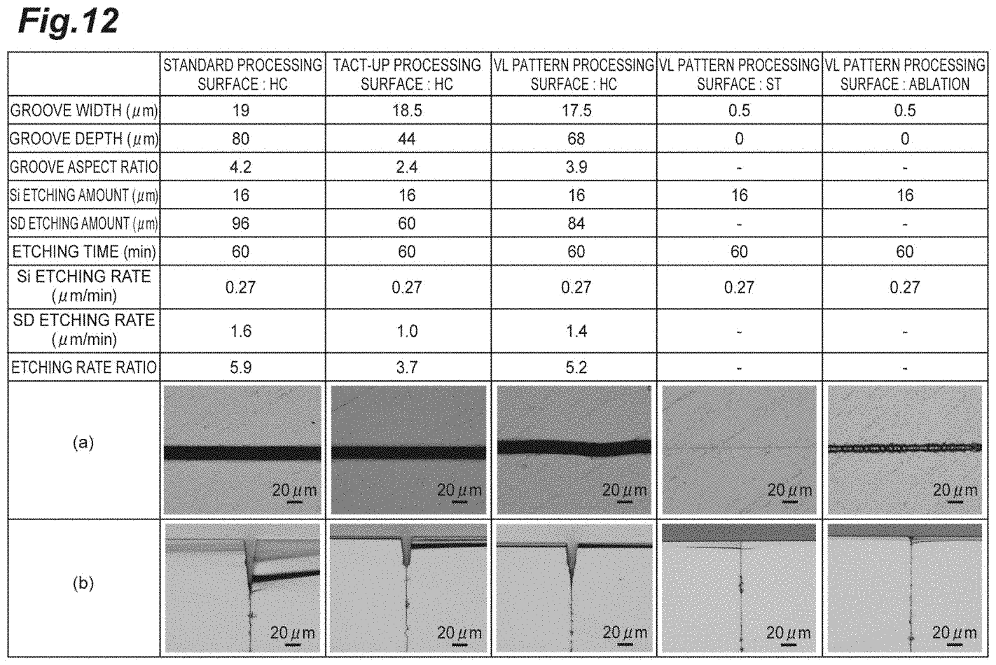

In a first experiment (see FIGS. 11 and 12), a plurality of lines to cut was set in stripes on a single crystal silicon substrate having a thickness of 400 μm, at an interval of 2 mm. Then, a plurality of rows of modified regions arranged in a thickness direction of the single crystal silicon substrate was formed in the single crystal silicon substrate along each of the plurality of lines to cut. (a) in FIG. 11 is a section picture (accurately, picture of a cut surface when the single crystal silicon substrate is cut before reactive ion etching described later is performed) of the single crystal silicon substrate after the modified region is formed. (b) in FIG. 11 is a plan picture of the single crystal silicon substrate after the modified region is formed. Hereinafter, the thickness direction of the single crystal silicon substrate is simply referred to as “the thickness direction”, and one surface (in (a) in FIG. 11, upper surface of the single crystal silicon substrate) in a case where dry etching is performed on the single crystal silicon substrate from the one surface side is simply referred to as “one surface”.

In FIG. 11, “standard processing, surface: HC” means a state where one row of modified regions on one surface side is separated from the one surface, and a fracture reaches the one surface from the one row of modified regions, in a case where laser light is converged by natural spherical aberration (aberration which occurs naturally at a converging position in accordance with Snell's law or the like due to converging of the laser light on the object), and a state where fractures respectively extending from the modified region in the thickness direction are connected to each other. “Tact-up processing, surface: HC” means a state where one row of modified regions on one surface side is separated from the one surface, and a fracture reaches the one surface from the one row of modified regions, in a case where laser light is converged such that the length of a converging point in an optical axis direction becomes shorter than natural spherical aberration by aberration correction, and a state where fractures respectively extending from the modified region in the thickness direction are connected to each other at black streak portions viewed in (a) in FIG. 11.

“VL pattern processing surface: HC” means a state where one row of modified regions on one surface side is separated from the one surface, and a fracture reaches the one surface from the one row of modified regions, in a case where laser light is converged such that the length of the converging point in the optical axis direction becomes longer than natural spherical aberration by imparting aberration. “VL pattern processing surface: ST” means a state where one row of modified regions on one surface side is separated from the one surface, and a fracture does not reach the one surface from the one row of modified regions, in a case where laser light is converged such that the length of the converging point in the optical axis direction becomes longer than natural spherical aberration by imparting aberration. “VL pattern processing surface: ablation” means a state where one row of modified regions on one surface side is exposed to the one surface in a case where laser light is converged such that the length of the converging point in the optical axis direction becomes longer than natural spherical aberration by imparting aberration.

After the modified regions were formed as described above, reactive ion etching with CF₄ (carbon tetrafluoride) was performed on the one surface of the single crystal silicon substrate for 60 minutes. FIG. 12 illustrates results thereof. (a) in FIG. 12 is a plan picture of the single crystal silicon substrate after reactive ion etching is performed. (b) in FIG. 12 is a section picture (picture of a cut surface perpendicular to the line to cut) of the single crystal silicon substrate after reactive ion etching is performed.

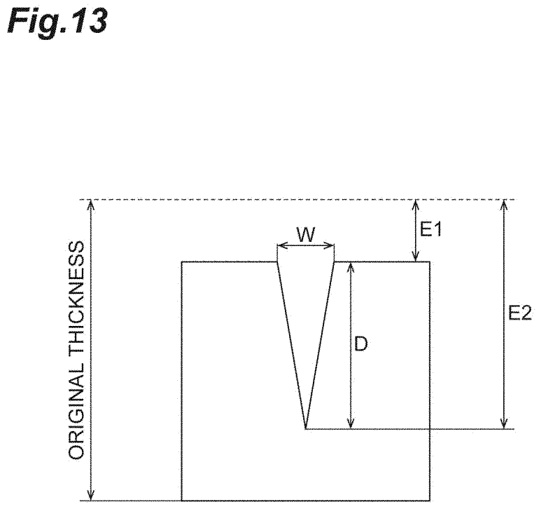

Here, definitions of terms illustrated in FIG. 12 will be explained with reference to FIG. 13. “Groove width” indicates a width W of an opening of a groove formed by dry etching. “Groove depth” indicates a depth D of the groove formed by dry etching. “Groove aspect ratio” indicates a value obtained by dividing D by W. “Si etching amount” indicates a value E1 obtained by subtracting the thickness of the single crystal silicon substrate subjected to dry etching from the thickness (original thickness) of the single crystal silicon substrate before dry etching is performed. “SD etching amount” indicates a value E2 obtained by adding D to E1. “Etching time” indicates a time T in which dry etching has been performed. “Si etching rate” indicates a value obtained by dividing E1 by T. “SD etching rate” indicates a value obtained by dividing E2 by T. “Etching rate ratio” indicates a value obtained by dividing E2 by E1.

The followings are understood from the results of the first experiment illustrated in FIG. 12. That is, if the fracture reaches one surface (one surface in a case where dry etching is performed on the single crystal silicon substrate from the one surface side), dry etching progresses selectively (that is, at a high etching rate ratio) from the one surface side along the fracture within a range in which fractures are connected to each other. Thus, a groove having an opening which is narrow in width and is deep (that is, the groove aspect ratio is high) is formed (comparison of “VL pattern processing surface: ST” and “VL pattern processing surface: ablation” to “standard processing surface: HC”). The fracture significantly contributes to selective progress of dry etching more than the modified region itself (comparison of “VL pattern processing surface: HC” and “VL pattern processing surface: ablation” to “standard processing surface: HC”). If the fractures extending from the modified regions in the thickness direction are not connected to each other, selective progress of dry etching is stopped at a portion (black streak portion viewed in (a) in FIG. 11) in which the fractures are not connected to each other (comparison of “tact-up processing surface: HC” to “standard processing surface: HC”). Stopping the selective progress of dry etching means that a progress speed of dry etching decreases.

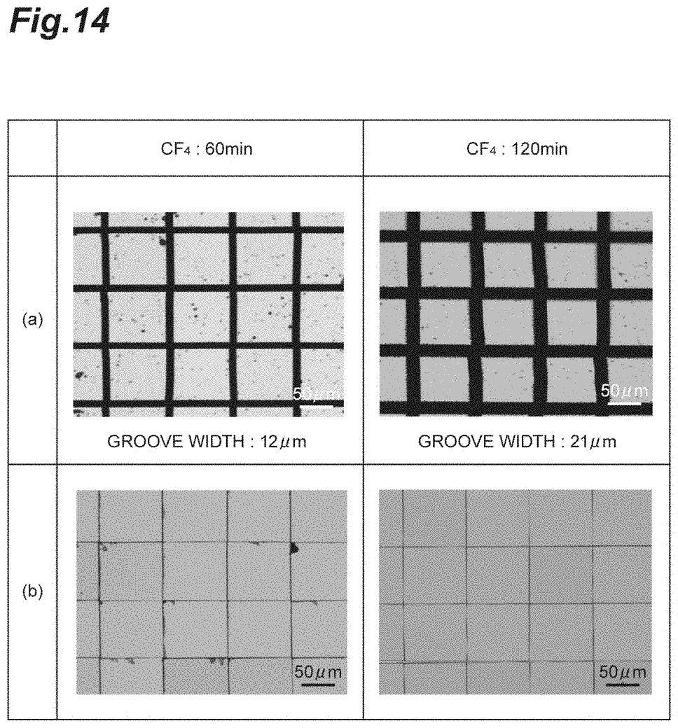

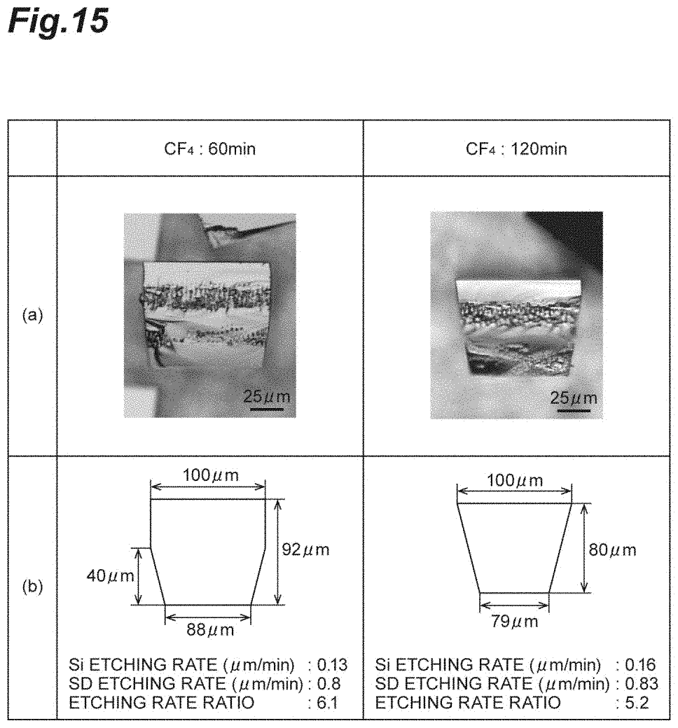

In a second experiment (see FIGS. 14 and 15), a plurality of lines to cut was set in stripes on a single crystal silicon substrate having a thickness of 100 μm, at an interval of 100 μm. Then, two rows of modified regions arranged in a thickness direction of the single crystal silicon substrate were formed in the single crystal silicon substrate along each of the plurality of lines to cut. Here, a state where the modified regions adjacent to each other in the thickness direction are separated from each other, and fractures extending from the modified regions in the thickness direction reach both one surface and the other surface (surface on an opposite side of the one surface) occurred. Reactive ion etching with CF₄ was performed on the one surface of the single crystal silicon substrate.

FIGS. 14 and 15 illustrate results of the second experiment. In FIGS. 14 and 15, “CF₄: 60 min” indicates a case where reactive ion etching with CF₄ was performed for 60 minutes. “CF₄: 120 min” indicates a case where reactive ion etching with CF₄ was performed for 120 minutes. (a) in FIG. 14 is a plan picture (picture of the one surface) of the single crystal silicon substrate before reactive ion etching is performed. (b) in FIG. 14 is a bottom picture (picture of the other surface) of the single crystal silicon substrate after reactive ion etching is performed. (a) in FIG. 15 is a side picture of a single crystal silicon chip obtained by cutting the single crystal silicon substrate along each of the plurality of lines to cut. (b) FIG. 15 is a diagram illustrating dimensions of the single crystal silicon chip. In (a) and (b) in FIG. 15, the one surface of the single crystal silicon substrate is on the lower side.

The followings are understood from the results of the second experiment illustrated in FIGS. 14 and 15. That is, if the fracture reaches one surface (one surface in a case where dry etching is performed on the single crystal silicon substrate from the one surface side), dry etching progresses selectively (that is, at a high etching rate ratio) from the one surface side along the fracture within a range in which fractures are connected to each other. Thus, a groove having an opening which is narrow in width and is deep (that is, the groove aspect ratio is high) is formed. If fractures extending from the modified regions in the thickness direction reach both one surface and the other surface, it is possible to completely chip the single crystal silicon substrate only by dry etching. If an extension film stuck to the other surface of the single crystal silicon substrate is extended in a case of “CF₄: 60 min”, it is possible to cut the single crystal silicon substrate having a rectangular shape of 50 mm×50 mm into chips of 100 μm×100 μm at a ratio of 100%.

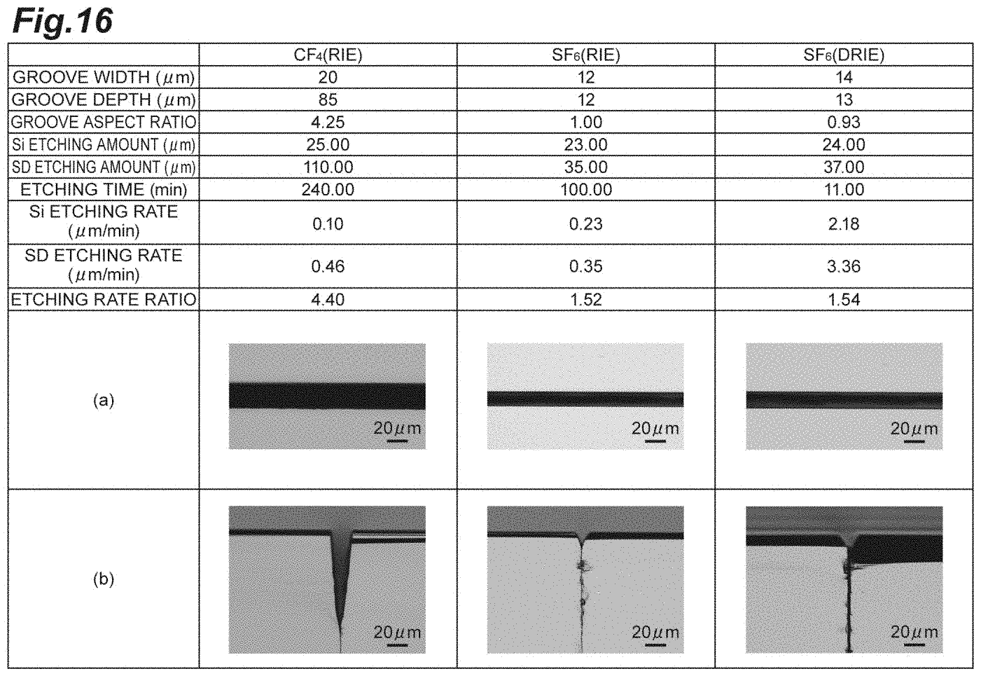

In a third experiment (see FIG. 16), a plurality of lines to cut was set in stripes on a single crystal silicon substrate having a thickness of 400 μm, at an interval of 2 mm. Then, a plurality of rows of modified regions arranged in a thickness direction of the single crystal silicon substrate was formed in the single crystal silicon substrate along each of the plurality of lines to cut. A state where one row of modified regions on one surface side is separated from the one surface, and a fracture reaches the one surface from the one row of modified regions, in a case where laser light is converged by natural spherical aberration, and a state where fractures extending from the modified regions in the thickness direction are connected to each other occurred. Reactive ion etching was performed on the one surface of the single crystal silicon substrate.

FIG. 16 illustrates results of the third experiment. In FIG. 16, “CF₄ (RIE)” indicates a case where reactive ion etching with CF₄ was performed by a reactive ion etching (RIE) apparatus, “SF₆ (RIE)” indicates a case where reactive ion etching with sulfur hexafluoride (SF₆) was performed by a RIE apparatus, and “SF₆ (DRIE)” indicates a case where reactive ion etching with SF₆ was performed by a deep reactive ion etching (DRIE) apparatus. (a) in FIG. 16 is a plan picture of the single crystal silicon substrate after reactive ion etching is performed. (b) in FIG. 16 is a section picture (picture of a cut surface perpendicular to the line to cut) of the single crystal silicon substrate after reactive ion etching is performed.

The followings are understood from the results of the third experiment illustrated in FIG. 16. That is, even though reactive ion etching with CF₄ requires longer time than reactive ion etching with SF₆, from a point that it is possible to ensure a high etching rate ratio and a high groove aspect ratio, reactive ion etching with CF₄ is more advantageous than reactive ion etching with SF₆, for ensuring the uniform Si etching amount.

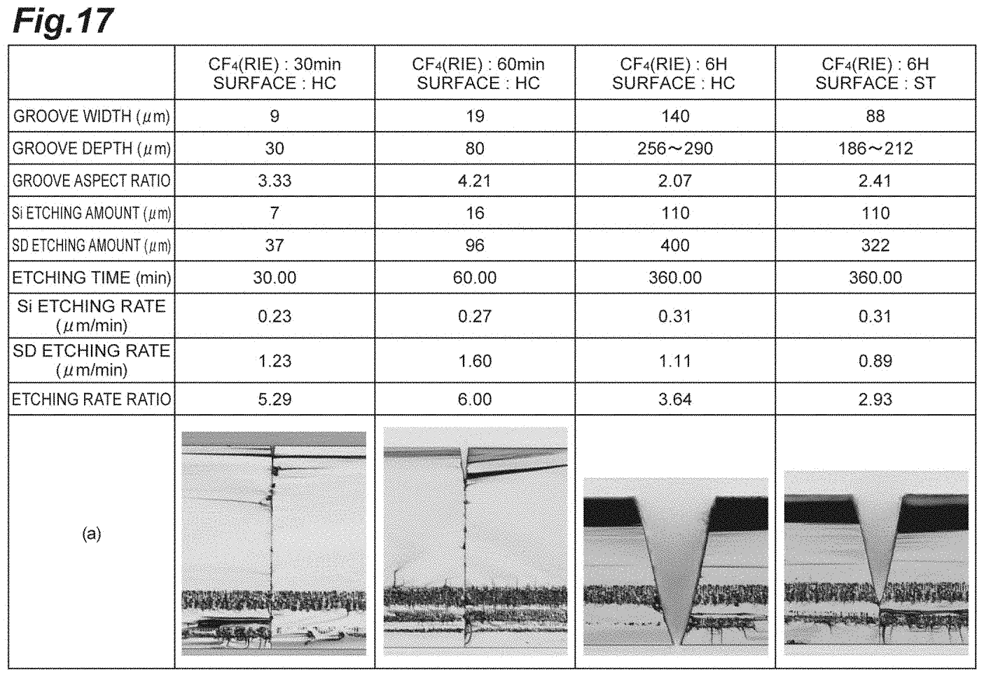

In a fourth experiment (see FIG. 17), a plurality of lines to cut was set in stripes on a single crystal silicon substrate having a thickness of 400 μm, at an interval of 2 mm. Then, a plurality of rows of modified regions arranged in a thickness direction of the single crystal silicon substrate was formed in the single crystal silicon substrate along each of the plurality of lines to cut. In FIG. 17, “CF₄ (RIE): 30 min, surface: HC”, “CF₄ (RIE): 60 min, surface: HC”, and “CF₄ (RIE): 6 H, surface: HC” mean a state where one row of modified regions on one surface side is separated from the one surface, and a fracture reaches the one surface from the one row of modified regions, in a case where laser light is converged by natural spherical aberration, and a state where fractures extending from the modified regions in the thickness direction are connected to each other. “CF₄ (RIE): 6 H, surface: ST” means a state where one row of modified regions on one surface side is separated from the one surface, and a fracture does not reach the one surface from the one row of modified regions, in a case where laser light is converged by natural spherical aberration, and a state where fractures extending from the modified regions in the thickness direction are connected to each other.

Reactive ion etching with CF₄ was performed on the one surface of the single crystal silicon substrate. In FIG. 17, “CF₄ (RIE): 30 min, surface: HC”, “CF₄ (RIE): 60 min, surface: HC”, “CF₄ (RIE): 6 H, surface: HC”, and “CF₄ (RIE): 6 H, surface: ST” mean that reactive ion etching with CF₄ was performed for 30 minutes, 60 minutes, 6 hours, and 6 hours, respectively, by the RIE apparatus.

FIG. 17 illustrates results of the fourth experiment. (a) in FIG. 17 is a section picture (picture of a cut surface perpendicular to the line to cut) of the single crystal silicon substrate after reactive ion etching is performed.

The followings are understood from the results of the fourth experiment illustrated in FIG. 17. That is, if the fracture reaches one surface (one surface in a case where dry etching is performed on the single crystal silicon substrate from the one surface side), selective progress of dry etching does not stop (that is, a high etching rate ratio is maintained) in a range in which fractures are connected to each other. Even though the fracture does not reach the one surface, etching from the one surface is in progress. If the fracture appears to the one surface, selective progress of dry etching starts along the fracture. Since it is difficult to stop extension of the fracture at a predetermined depth from the one surface, a timing at the fracture appears to the one surface by the progress of etching varies easily depending on a place. As a result, the width and the depth of an opening of a groove to be formed vary easily depending on the place. Thus, when one row of modified regions on one surface side is formed, it is very important to form the modified regions such that a fracture reaches the one surface.

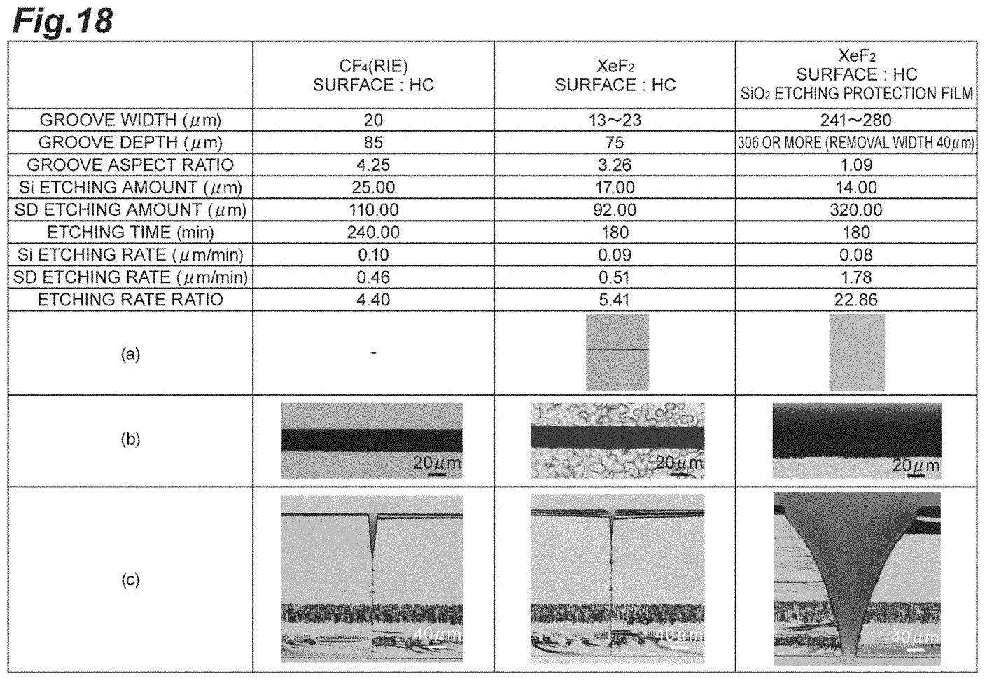

In a fifth experiment (see FIG. 18), a plurality of lines to cut was set in grid on a single crystal silicon substrate having a thickness of 320 μm, at an interval of 3 mm. Then, a plurality of rows of modified regions arranged in a thickness direction of the single crystal silicon substrate was formed in the single crystal silicon substrate along each of the plurality of lines to cut. A state where one row of modified regions on one surface side is separated from the one surface, and a fracture reaches the one surface from the one row of modified regions, in a case where laser light is converged by natural spherical aberration, and a state where fractures extending from the modified regions in the thickness direction are connected to each other occurred.

Reactive ion etching was performed on the one surface of the single crystal silicon substrate. In FIG. 18, “CF₄ (RIE), surface: HC” means that reactive ion etching with CF₄ was performed by a RIE apparatus. “XeF₂, surface: HC” means that reactive gas etching with xenon difluoride (XeF₂) was performed by a sacrificial layer etcher apparatus. “XeF₂, surface: HC, SiO₂ etching protection layer” means that reactive gas etching with XeF₂ was performed by a sacrificial layer etcher apparatus in a state where an etching protection layer made of silicon dioxide (SiO₂) was formed on one surface of the single crystal silicon substrate, and a fracture reaches a surface (outer surface on an opposite side of the single crystal silicon substrate) of the etching protection layer from one row of modified regions on the one surface side.

FIG. 18 illustrates results of the fifth experiment. (a) in FIG. 18 is a plan picture of the single crystal silicon substrate before reactive ion etching is performed. (b) in FIG. 18 is a plan picture of the single crystal silicon substrate after reactive ion etching is performed. (c) in FIG. 18 is a section picture (picture of a cut surface perpendicular to the line to cut) of the single crystal silicon substrate after reactive ion etching is performed. A removal width is a width of an opening on the other surface of the single crystal silicon substrate in a case where the groove reaches the other surface.

The followings are understood from the results of the fifth experiment illustrated in FIG. 18. That is, if the etching protection layer made of SiO₂ is not formed on one surface of the single crystal silicon substrate (the one surface in a case where dry etching is performed on the single crystal silicon substrate from the one surface side), a difference between reactive ion etching with CF₄ and reactive gas etching with XeF₂ is not large from a point of ensuring a high etching rate ratio and a high groove aspect ratio. If the etching protection layer made of SiO₂ is formed on the one surface of the single crystal silicon substrate, and the fracture reaches the surface of the etching protection layer from one row of modified regions on the one surface side, the etching rate ratio and the groove aspect ratio increase significantly.

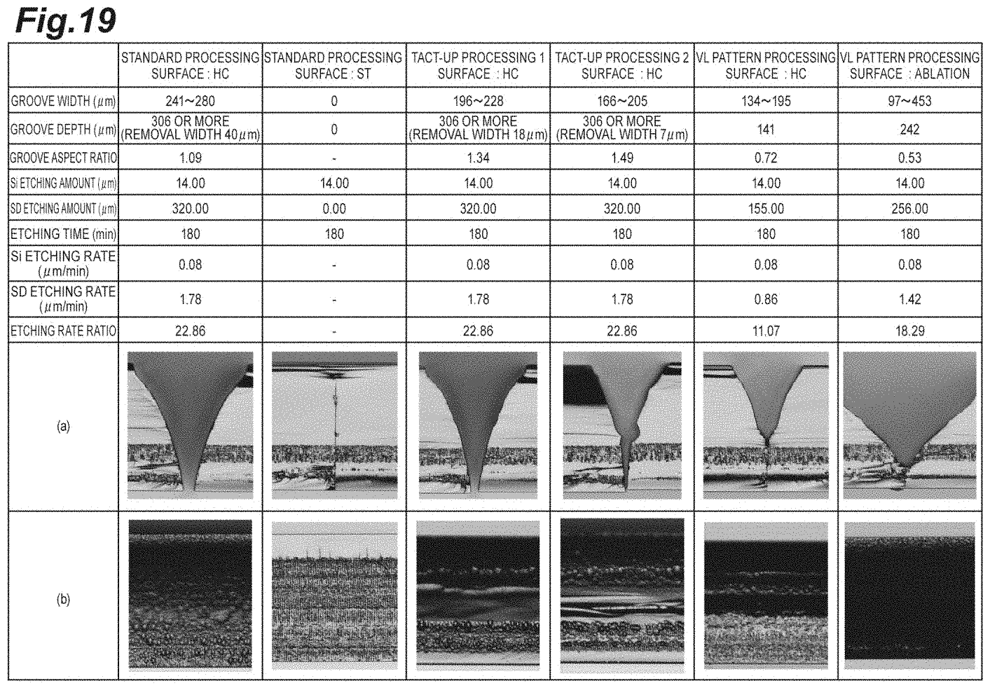

In a sixth experiment (see FIG. 19), a plurality of lines to cut was set in grid on a single crystal silicon substrate which has a thickness of 320 μm and in which an etching protection layer made of SiO₂ is formed on one surface, at an interval of 3 mm. Then, a plurality of rows of modified regions arranged in a thickness direction of the single crystal silicon substrate was formed in the single crystal silicon substrate along each of the plurality of lines to cut. Reactive gas etching with XeF₂ was performed on the one surface of the single crystal silicon substrate by a sacrificial layer etcher apparatus for 180 minutes.

In FIG. 19, “standard processing, surface: HC” means a state where the modified regions adjacent to each other in the thickness direction are separated from each other, one row of modified regions on one surface side is separated from the one surface, and a fracture reaches a surface (outer surface on an opposite side of the single crystal silicon substrate) of the etching protection layer from the one row of modified regions, and a state where fractures extending from the modified regions in the thickness direction are connected to each other. “Standard processing, surface: ST” means a state where the modified regions adjacent to each other in the thickness direction are separated from each other, one row of modified regions on the one surface side is separated from the one surface, and a fracture does not reach the one surface from the one row of modified regions, and a state where fractures extending from the modified regions in the thickness direction are connected to each other.

“Tact-up processing 1, surface: HC” means a state where the modified regions adjacent to each other in the thickness direction are separated from each other, one row of modified regions on the one surface side is separated from the one surface, and a fracture reaches the surface of the etching protection layer from the one row of modified regions, and a state where fractures extending from the modified regions in the thickness direction are connected to each other. “Tact-up processing 2, surface: HC” means a state where the modified regions adjacent to each other in the thickness direction are separated from each other, one row of modified regions on the one surface side is separated from the one surface, and a fracture reaches the surface of the etching protection layer from the one row of modified regions, and a state where some of fractures extending from the modified regions in the thickness direction are connected to each other.

“VL pattern processing, surface: HC” means a state where the modified regions adjacent to each other in the thickness direction are connected to each other, one row of modified regions on the one surface side is separated from the one surface, and a fracture reaches the surface of the etching protection layer from the one row of modified regions. “VL pattern processing, surface: ablation” means a state where the modified regions adjacent to each other in the thickness direction are connected to each other, and the one row of modified regions on the one surface side is exposed to the surface of the etching protection layer.

FIG. 19 illustrates results of the sixth experiment. (a) in FIG. 19 is a section picture (picture of a cut surface perpendicular to the line to cut) of the single crystal silicon substrate after reactive ion etching is performed. (b) in FIG. 19 is a picture of a cut surface of the single crystal silicon substrate after reactive ion etching is performed.

The followings are understood from the results of the fifth experiment illustrated in FIG. 19. That is, if the fracture reaches the surface of the etching protection layer, dry etching progresses selectively (that is, at a high etching rate ratio) from the one surface side along the fracture within a range in which fractures are connected to each other. Thus, a groove having an opening which is narrow in width and is deep (that is, the groove aspect ratio is high) is formed. If the fractures extending from the modified regions in the thickness direction are not connected to each other, dry etching progresses isotropically at a portion in which the fractures are not connected to each other (picture of the (a) field in “tact-up processing 2, surface: HC”.

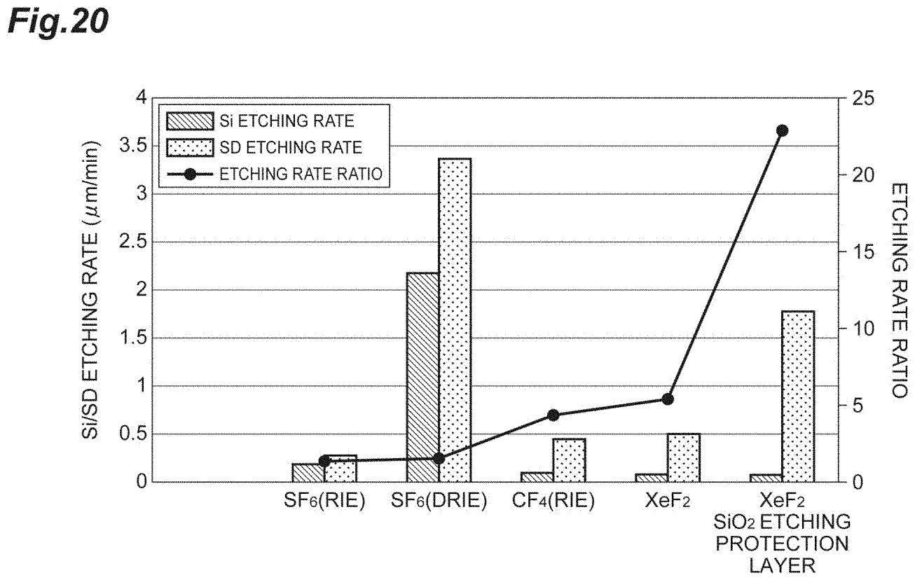

The followings are understood from the experimental results on the above-described object cutting methods. That is, presuming that the fracture reaches the one surface from one row of modified regions on the one surface side (one surface in a case where dry etching is performed on the single crystal silicon substrate from the one surface side) (in a case where the etching protection layer made of SiO₂ is formed on the one surface of the single crystal silicon substrate, the fracture reaches the surface of the etching protection layer), within a range in which fractures are connected to each other, as illustrated in FIG. 20, reactive ion etching with CF₄ and reactive gas etching with XeF₂ can ensure a high reactive gas etching rather than reactive ion etching with SF₆. Further, if the etching protection layer made of SiO₂ is formed on the one surface of the single crystal silicon substrate, and the fracture reaches the surface of the etching protection layer from one row of modified regions on the one surface side, the etching rate ratio increases significantly. Focusing on the groove aspect ratio, reactive ion etching with CF₄ is particularly excellent. Reactive gas etching with XeF₂ is advantageous from a point of preventing the decrease of strength of the single crystal silicon substrate by plasma.

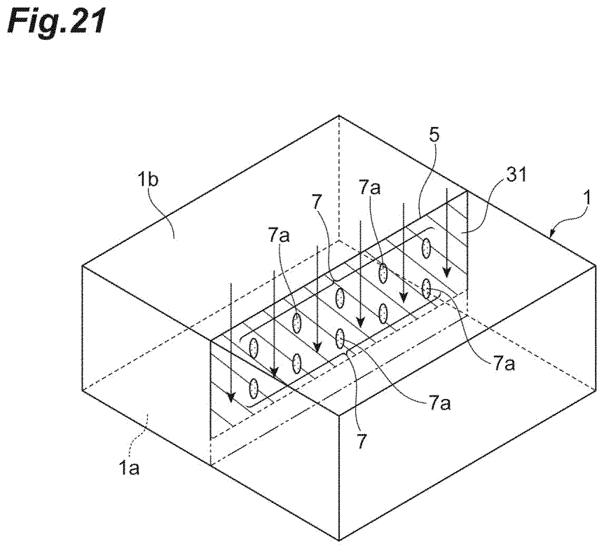

The principle in which dry etching selectively progresses along a fracture will be explained. If the converging point P of laser light L oscillating in a pulsating manner is located in the object 1, and the converging point P is relatively moved along the line 5 to cut, as illustrated in FIG. 21, a plurality of modified spots 7a arranged along the line 5 to cut is formed in the object 1. The plurality of modified spots 7a arranged along the line 5 to cut corresponds to one row of modified regions 7.

In a case where a plurality of rows of modified regions 7 arranged in the thickness direction of the object 1 is formed in the object 1, if a fracture 31 is formed to extend between the second main surface 1b and one row of modified regions 7 on the second main surface 1b (second main surface 1b in a case where dry etching is performed on the object 1 from the second main surface 1b side) side of the object 1, an etching gas enters into fractures 31 having intervals of several nm to several μm, in a manner as with capillarity (see an arrow in FIG. 21). Thus, it is supposed that dry etching selectively progresses along the fracture 31.

From this, if the fracture 31 is formed to extend between the modified regions 7 adjacent to each other among the plurality of rows of modified regions 7, it is supposed that dry etching selectively progresses deeper. Further, if the fracture 31 is formed to extend between the modified spots 7a adjacent to each other among the plurality of modified spots 7a arranged along the line 5 to cut, it is supposed that dry etching selectively progresses with higher efficiency. At this time, the etching gas comes into contact with each of the modified spots 7a from the surroundings of the modified spot 7a. Thus, it is supposed that the modified spot 7a having a size of about several μm is removed quickly.

Here, the fracture 31 is different from microcracks included in each modified spot 7a, microcracks randomly formed around each modified spot 7a, and the like. Here, the fracture 31 is a fracture which is parallel to the thickness direction of the object 1 and extends along a plane including the line 5 to cut. In a case where the fracture 31 herein is formed in the single crystal silicon substrate, surfaces (fracture surface facing each other at a distance of several nm to several μm) formed by the fracture 31 are surfaces on which single crystal silicon is exposed. The modified spot 7a formed in the single crystal silicon substrate includes a polycrystalline silicon region, a high dislocation density region, and the like.

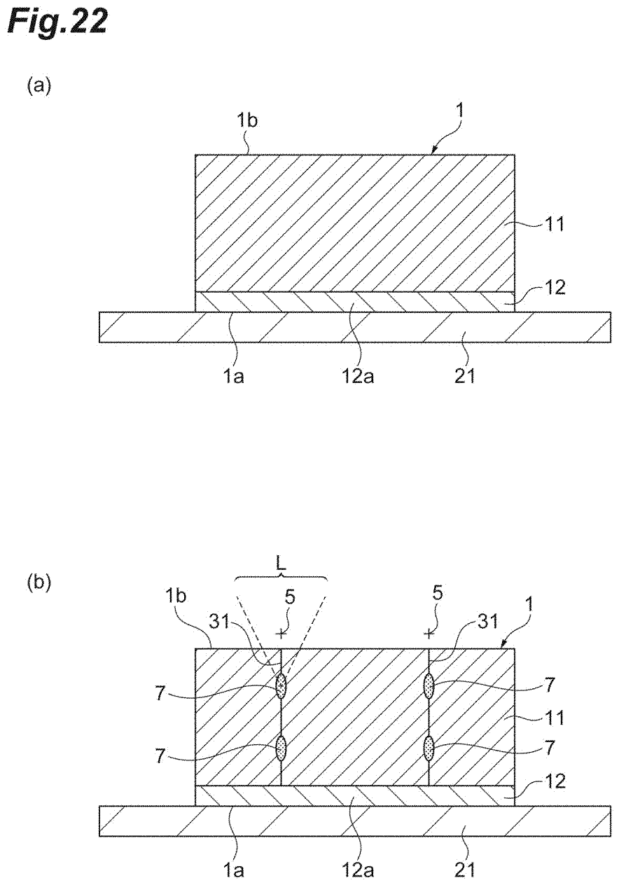

Next, an object cutting method according to one embodiment will be described. Each component illustrated in FIGS. 22 to 26 is schematic, and aspect ratios and the like of each component are different from those of the practical one.

Firstly, as a first step, as illustrated in FIG. 22(a), an object to be processed 1 including a single crystal silicon substrate 11 and a functional device layer 12 provided on a first main surface 1a side is prepared, and a protective film 21 is stuck to the first main surface 1a of the object 1.

After the first step, as the second step, as illustrated in FIG. 22(b), the object 1 is irradiated with a laser light L by using a second main surface 1b as a laser light incident surface, so a plurality of rows of modified regions 7 are formed in the single crystal silicon substrate 11 along each of a plurality of lines to cut 5 and a fracture 31 is formed in the object 1 along each of the plurality of lines to cut 5. The plurality of rows of modified regions 7 formed along each of the plurality of lines to cut 5 are arranged in a thickness direction of the object 1. Each of the plurality of rows of modified regions 7 is constituted by a plurality of modified spots 7a arranged along the lines to cut 5 (see FIG. 21). The fracture 31 extends between one row of modified regions 7 positioned on the second main surface 1b side and the second main surface 1b, and between the modified regions 7 adjacent to each other in the plurality of rows of modified regions 7. Further, the fracture 31 extends between the modified spots 7a adjacent to each other in the plurality of modified spots 7a (see FIG. 21).

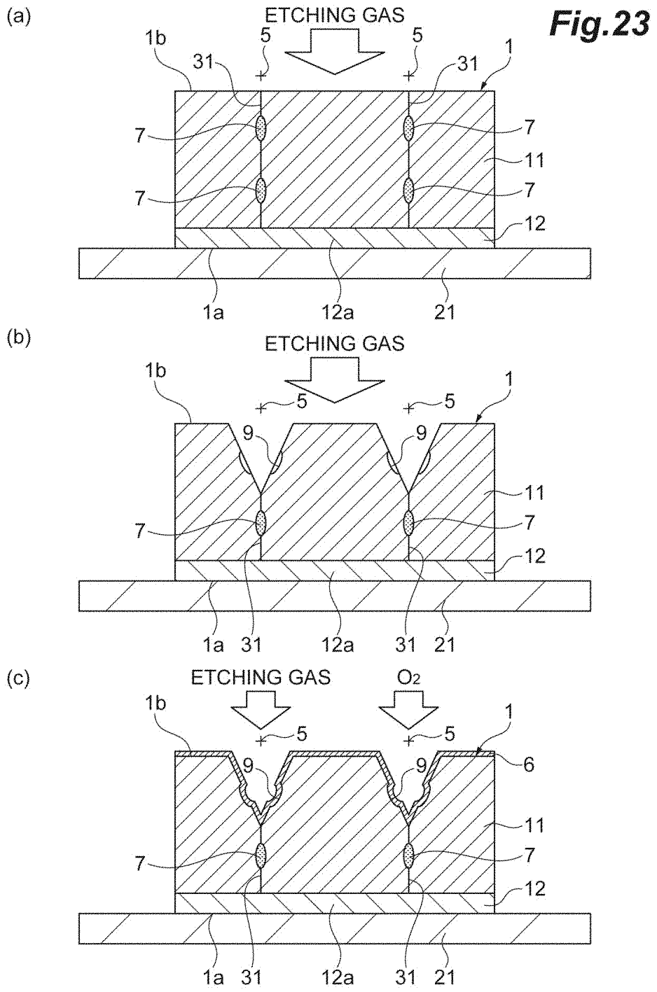

After the second step, as the third step, as illustrated in FIG. 23(a), the reactive ion etching is performed on the object 1 from the second main surface 1b side, so grooves 32 are formed in the object 1 along each of the plurality of lines to cut 5 as illustrated in FIG. 23(b). The groove 32 is, for example, a V groove (groove having a V-shaped cross section) opening to the second main surface 1b. Here, the reactive ion etching using CF₄ or SF₆ is performed on the object 1 from the second main surface 1b side using CF₄ or SF₆. In addition, by removing one row of modified regions 7 positioned on the second main surface 1b side from the plurality of rows of modified regions 7, the reactive ion etching is performed on the object 1 from the second main surface 1b side so that an uneven region 9 having an uneven shape corresponding to one row of modified region 7 removed is formed on the inner surface of the groove 32. Note that in the case of forming the uneven region 9, the reactive ion etching is preferably performed until the modified region 7 (modified spot 7a) is completely removed from the inner surface of the groove 32. On the other hand, the reactive ion etching may not be performed until the uneven region 9 is completely removed.

In the third step, as shown in FIG. 23(c), during the reactive ion etching, O₂ (oxygen) is mixed into the etching gas (that is, CF₄ or SF₆) while the reactive ion etching is performed to form the black silicon layer 6 on the second main surface 1b of the object 1 and the inner surface of the groove 32. The black silicon layer 6 is provided so as to be stacked on the second main surface 1b of the object 1, and is provided so as to enter the groove 32. The black silicon layer 6 exists so as to cover the second main surface 1b side of the object 1. In this way, the selective progress of the reactive ion etching stops or ends.

The black silicon layer 6 is formed by a black silicon phenomenon in which SiO₂-based materials which are a reaction product during the dry etching are deposited on the surface to be etched. The black silicon layer 6 includes fine needle-like irregularities. The ending of the reactive ion etching is a state in which the reactive ion etching does not proceed any more. The timing at which O₂ is mixed is a timing at which the depth of the groove 32 becomes a preset desired (arbitrary) depth. The timing at which O₂ is mixed can be set by at least any one of calculation, experiment, and experience using, for example, an etching rate ratio and the like. The amount of O₂ mixed may be a predetermined amount or larger which can form the black silicon layer 6. The amount of O₂ mixed may be a preset constant amount or a variable amount.

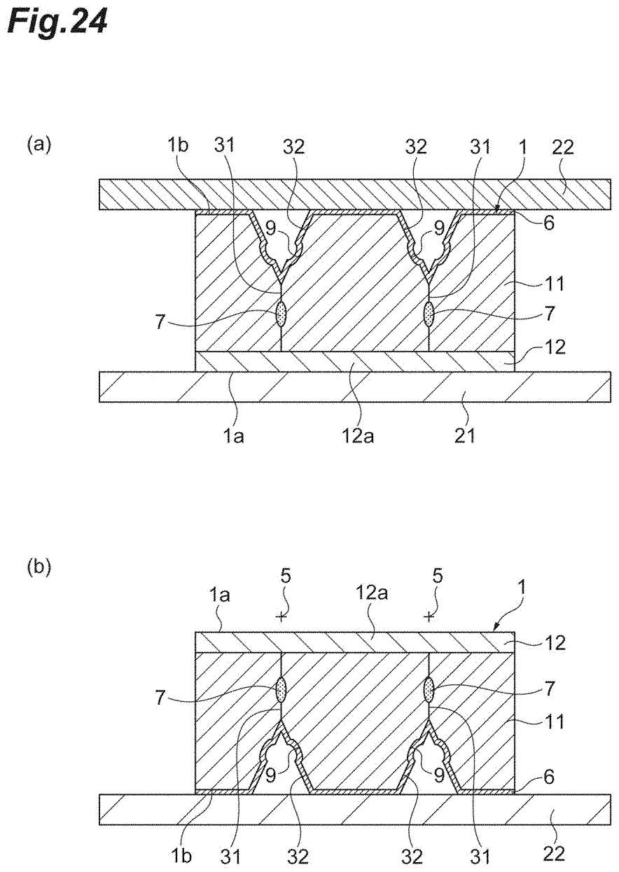

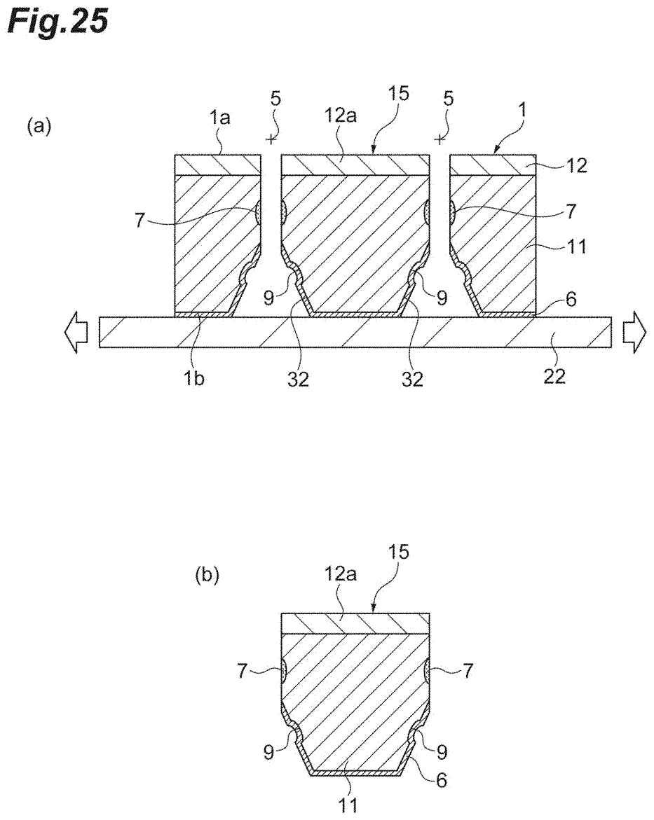

After the third step, as a fourth step, as illustrated in FIG. 24(a), an extension film 22 is stuck to the black silicon layer on the second main surface 1b of the object 1 (that is, stuck to the second main surface 1b side of the object 1), and as illustrated in FIG. 24(b), the protective film 21 is removed from the first main surface 1a of the object 1. Subsequently, as illustrated in FIG. 25(a), by extending the extension film 22, the object 1 is cut into a plurality of semiconductor chips 15 along each of the plurality of lines to cut 5, and as illustrated in FIG. 25(b), the semiconductor chips 15 are picked up.

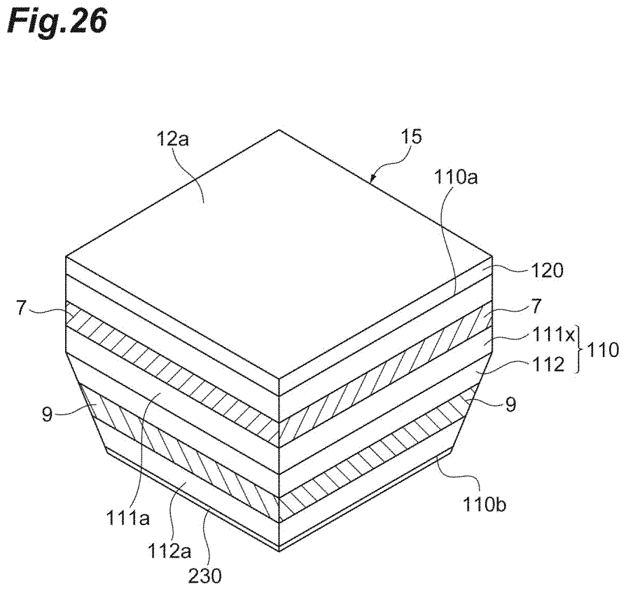

The semiconductor chip 15 obtained by the object cutting method described above will be described. As illustrated in FIG. 26, the semiconductor chip 15 includes a single crystal silicon substrate 110, a functional device layer 120 provided on a first surface 110a side of the single crystal silicon substrate 110, and an etching protection layer 230 formed on a second surface 110b (surface on an opposite side to the first surface 110a) of the single crystal silicon substrate 110. The single crystal silicon substrate 110 is a portion cut out from the single crystal silicon substrate 11 of the object 1. The functional device layer 120 is a portion cut out from the functional device layer 12 of the object 1 and includes one functional device 12a. The etching protection layer 230 is a portion cut out from the etching protection layer 23.

The single crystal silicon substrate 110 includes a first portion 111x and a second portion 112. The first portion 111x is a portion on the first surface 110a side. The second portion 112 is a portion on the second surface 110b side. The second portion 112 has a shape which becomes thinner as becoming farther from the first surface 110a. The second portion 112 corresponds to a portion (that is, a portion at which the reactive ion etching progresses) at which the groove 32 is formed in the single crystal silicon substrate 11 of the object 1. As an example, the first portion 111x has a quadrangular plate shape (rectangular parallelepiped shape), and the second portion 112 has a truncated quadrangular pyramid shape which becomes thinner as becoming farther from the first portion 111x.

A modified region 7 is formed on the side surface 111a of the first portion 111x to have a band shape. That is, the modified regions 7 extend in a direction parallel to the first surface 110a along each side surface 111a, on each side surface 111a. The modified region 7 positioned on the first surface 110a side is separated from the first surface 110a. The modified region 7 is constituted by the plurality of modified spots 7a (see FIG. 21). The plurality of modified spots 7a are arranged in a direction parallel to the first surface 110a along each side surface 111a, on each side surface 111a. The modified region 7 (more specifically, each modified spot 7a) includes a polycrystalline silicon region, a high dislocation density region, and the like.

The uneven region 9 is formed on the side surface 112a of the second portion 112 to have a band shape. That is, the uneven regions 9 extend in a direction parallel to the second surface 110b along each side surface 112a, on each side surface 112a. The uneven region 9 on the second surface 110b side is separated from the second surface 110b. The uneven region 9 is formed by removing the modified region 7 on the second main surface 1b side of the object 1 by the reactive ion etching. Therefore, the uneven region 9 has the uneven shape corresponding to the modified region 7, and single crystal silicon is exposed in the uneven region 9. That is, the side surface 112a of the second portion 112 is a surface where the single crystal silicon is exposed, including the uneven surface of the uneven region 9.

Note that the semiconductor chip 15 may not include the etching protection layer 230. Such a semiconductor chip 15 is obtained, for example, in the case where the reactive ion etching is performed from the second main surface 1b side to remove the etching protection layer 23.

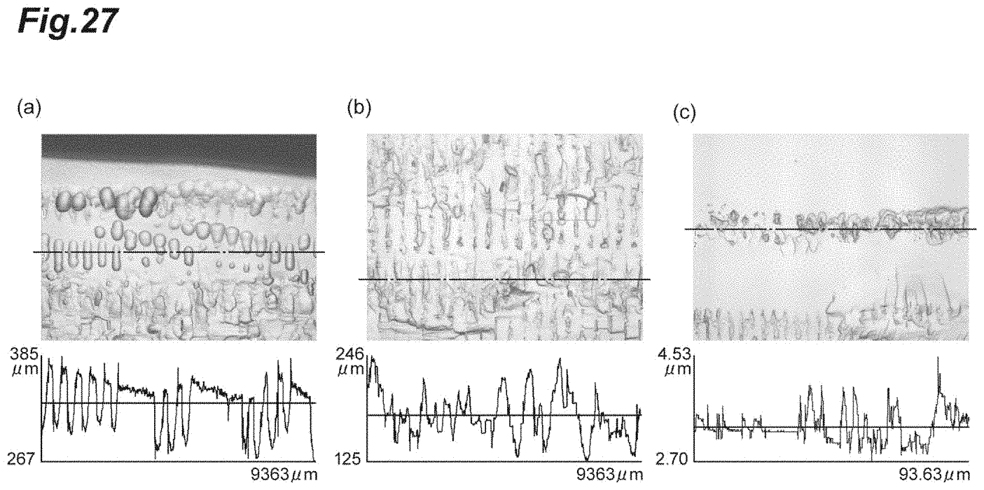

In FIG. 27(a), an upper part is a picture of the uneven region 9, and a lower part is an uneven profile of the uneven region 9 along a one-dot chain line of the upper part. In FIG. 27(b), the upper part is a picture of the modified region 7, and the lower part is an uneven profile of the modified region 7 along a one-dot chain line of the upper end. Comparing these drawings, it is understood that in the uneven region 9, only a plurality of relatively large recessed parts tend to be formed, whereas in the modified region 7, not only a plurality of relatively large recessed parts but also relatively large protruding parts tend to be formed at random. FIG. 27(c) illustrates a picture and an uneven profile of “the modified region 7 positioned on the second main surface 1b side” in the case where the object 1 is cut without performing the reactive ion etching on the object 1 from the second main surface 1b side. Even in the modified region 7 in this case, there is also a tendency in which not only a plurality of relatively large recessed parts but also a plurality of relatively large protruding parts tend to be formed at random. That is, it is understood that the tendency in which only a plurality of relatively large recessed parts are formed in the uneven region 9 is caused by removing the modified region 7 by the reactive ion etching. In the semiconductor chip 15, in addition to the uneven region 9, the black silicon layer 6 can function as a gettering region that traps impurities.

As described above, in the object cutting method, the reactive ion etching is performed, from the second main surface 1b side, on the object 1 in which the fracture 31 is formed to extend between at least one row of modified regions 7 and the second main surface 1b. As a result, the reactive ion etching selectively progresses along the fracture 31 from the second main surface 1b, and the groove 32 having a narrow and deep opening is formed along each of the plurality of lines to cut 5. Here, it is possible to end the progress of the reactive ion etching using the black silicon layer 6 by forming the black silicon layer 6 on the second main surface 1b of the object 1 and the inner surface of the groove 32 while the reactive ion etching is performed. That is, it is possible to control the progress of the reactive ion etching. The reactive ion etching can reliably end at any timing to enable high-quality etching dicing. Since reactive ion etching can stop during the etching, it is possible to prevent wraparound of an etching gas into the functional device layer 12.

In the object cutting method, in the second step, by forming the plurality of rows of modified regions 7 arranged in the thickness direction of the object 1, at least one row of modified regions 7 may be formed along each of the plurality of lines to cut 5, and the fracture 31 may be formed to extend between the modified regions 7 adjacent to each other in the plurality of rows of modified regions 7. In this way, it is possible to progress the reactive ion etching deeper and selectively.

In the object cutting method, in the second step, the at least one row of modified regions 7 may be formed along each of the plurality of lines to cut 5 by forming the plurality of modified spots 7a arranged along each of the plurality of lines to cut 5, and the fracture 31 may be formed to extend between the modified spots 7a adjacent to each other among the plurality of modified spots 7a. In this way, it is possible to selectively progress the reactive ion etching with higher efficiency.

In the object cutting method, in the third step, the black silicon layer 6 is formed by mixing O₂ into the etching gas. As a result, the formation of the black silicon layer 6 can be specifically realized.

In the object cutting method, in the third step, O₂ is mixed into the etching gas when the groove 32 has a predetermined depth. As a result, the progress of the reactive ion etching can end by Banning the black silicon layer 6 so that the groove 32 with a predetermined depth is formed.

The object cutting method include a fourth step of, after the third step, cutting the object 1 into the plurality of semiconductor chips 15 along each of the plurality of lines to cut 5 by sticking the extension film 22 to the second main surface 1b side and extending the extension film 22. As a result, it is possible to reliably cut the object 1 into the plurality of semiconductor chips 15 along each of the lines to cut 5. Further, since the plurality of semiconductor chips 15 are separated from each other on the extension film 22, the pickup of the semiconductor chips 15 can be facilitated.

The embodiment of the present invention has been described above; however, an aspect of the present invention is not limited to the above-mentioned embodiment.

In the above-mentioned embodiment, for example, a pressure-sensitive tape having vacuum resistance, a UV tape, or the like can be used as the protective film 21. Instead of the protective film 21, a wafer fixing jig having etching resistance may be used.

In the above-mentioned embodiment, the number of rows of modified regions 7 foamed in the single crystal silicon substrate 11 along each of the plurality of lines 5 to cut is not limited to a plurality of rows and may be one row. That is, at least one row of modified regions 7 may be formed in the single crystal silicon substrate 11 along each of the plurality of lines 5 to cut. In a case where a plurality of rows of modified regions 7 is formed in the single crystal silicon substrate 11 along each of the plurality of lines 5 to cut, the modified regions 7 adjacent to each other may be connected to each other.

In the above-mentioned embodiment, the fracture 31 may be formed to extend between at least one row of modified regions 7 and the second main surface 1b of the object 1. That is, the fracture 31 may not reach the second main surface 1b if the fracture is partial. Further, the fracture 31 may not extend between the modified spots 7a adjacent to each other so long as the fracture 31 is partial. The fracture 31 may not extend between the modified regions 7 adjacent to each other so long as the fracture 31 is partial. The fracture 31 may or may not reach the first main surface 1a of the object 1.

In the above-mentioned embodiment, dry etching may be performed from the second main surface 1b side such that the plurality of rows of modified regions 7 is removed, and thereby the uneven region 9 which has an uneven shape corresponding to the plurality of rows of removed modified regions 7 and in which single crystal silicon is exposed is formed in the inner surface of the groove 32. As dry etching, reactive ion etching with a gas other than CF₄ or SF₆ may be performed.

### REFERENCE SIGNS LIST

1 Object

1a First main surface

1b Second main surface

5 Line to cut

6 Black silicon layer

7 Modified region

7a Modified spot

11 Single crystal silicon substrate

12 Functional device layer

15 Semiconductor chip

22 Extension film

31 Fracture

32 Groove

L Laser light

1. An object cutting method, comprising:
a first step of preparing an object to be processed including a single crystal silicon substrate and a functional device layer provided on a first main surface side;
a second step of, after the first step, irradiating the object with a laser light to form at least one row of modified regions in the single crystal silicon substrate along each of a plurality of lines to cut and to form a fracture in the object so as to extend between the at least one row of modified regions and a second main surface of the object along each of the plurality of lines to cut; and
a third step of, after the second step, performing reactive ion etching on the object from the second main surface side to form a groove opening to the second main surface, in the object along each of the plurality of lines to cut,
wherein in the third step, a black silicon layer is formed on the second main surface of the object and an inner surface of the groove while the reactive ion etching is performed.

2. The object cutting method according to claim 1, wherein in the second step, the at least one row of modified regions is formed along each of the plurality of lines to cut by forming the plurality of rows of modified regions arranged in a thickness direction of the object, and the fracture is formed to extend between the modified regions adjacent to each other in the plurality of rows of modified regions.

3. The object cutting method according to claim 1, wherein in the second step, the at least one row of modified regions is formed along each of the plurality of lines to cut by forming a plurality of modified spots arranged along each of the plurality of lines to cut, and the fracture is formed to extend between the modified spots adjacent to each other among the plurality of modified spots.

4. The object cutting method according to claim 1, wherein in the third step, the black silicon layer is formed by mixing oxygen into an etching gas.

5. The object cutting method according to claim 4, wherein in the third step, the oxygen is mixed into the etching gas when the groove has a predetermined depth.

6. The object cutting method according to claim 1, further comprising: a fourth step of, after the third step, cutting the object into a plurality of semiconductor chips along each of the plurality of lines to cut by sticking an extension film to the second main surface side and extending the extension film.

7. The object cutting method according to claim 2, wherein in the second step, the at least one row of modified regions is formed along each of the plurality of lines to cut by forming a plurality of modified spots arranged along each of the plurality of lines to cut, and the fracture is formed to extend between the modified spots adjacent to each other among the plurality of modified spots.

8. The object cutting method according to claim 2, wherein in the third step, the black silicon layer is formed by mixing oxygen into an etching gas.

9. The object cutting method according to claim 3, wherein in the third step, the black silicon layer is formed by mixing oxygen into an etching gas.

10. The object cutting method according to claim 2, further comprising: a fourth step of, after the third step, cutting the object into a plurality of semiconductor chips along each of the plurality of lines to cut by sticking an extension film to the second main surface side and extending the extension film.

11. The object cutting method according to claim 3, further comprising: a fourth step of, after the third step, cutting the object into a plurality of semiconductor chips along each of the plurality of lines to cut by sticking an extension film to the second main surface side and extending the extension film.

12. The object cutting method according to claim 4, further comprising: a fourth step of, after the third step, cutting the object into a plurality of semiconductor chips along each of the plurality of lines to cut by sticking an extension film to the second main surface side and extending the extension film.

13. The object cutting method according to claim 5, further comprising: a fourth step of, after the third step, cutting the object into a plurality of semiconductor chips along each of the plurality of lines to cut by sticking an extension film to the second main surface side and extending the extension film.
